(19) United States
(12) Patent Application Publication
(10) Pub. No.: US 2008/0231335 A1
(43) Pub. Date: Sep. 25, 2008

(54) CIRCUIT TO REDUCE DUTY CYCLE DISTORTION

(75) Inventor: Paul M. Werking, Rockford, MN (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 11/688,649

(22) Filed: Mar. 20, 2007

(51) Int. Cl. H03K 17/284; H03K 3/017

(52) U.S. Cl. 327/175; 702/106; 327/399

(57) ABSTRACT

A method and a circuit for correcting duty cycle distortion. A delay insertion gate corrects data dependent delay distortion that is generated by CMOS flip-flop circuits. The delay insertion gate includes two field effect transistors and a current mirror. The two transistors each respectively receive an input signal from an upstream circuit. At least one of the transistors is coupled to an output node. The output node temporarily holds a voltage state within the delay insertion gate, correcting any distortion in the duty cycle of the input signals.

### GOVERNMENT RIGHTS

The United States Government may have acquired certain rights in this invention pursuant to Contract No. DAAE30-01-0-0100 awarded by the Department of the Army.

### FIELD

The present invention relates generally to the field of sigma-delta digital-to-analog converters (DACs), phase locked loops (PLLs), delay locked loops (DLLs), and other timing generators.

### BACKGROUND

In many applications, such as data communications systems or sigma-delta digital-to-analog converters (DACs), it is important to accurately control the duty cycle of a digital waveform because it is the duty cycle of the waveform that contains information. In general, errors may be added to the duty cycle of a digital waveform (i.e., the waveform may be distorted) in one of two ways: either by data dependent variations in rise and fall times or by data dependent delays.

FIG. 1 shows how differences in rise and fall times can cause distortion, or errors, in the duty cycle of a digital waveform. In FIG. 1, three different rise times are shown: fast, nominal, and slow. The point in time at which the rising waveform crosses an arbitrary digital threshold, V_{T}, is denoted as either t_{R1}, t_{R2}, or t_{R3}, respectively. In a similar manner, the point in time at which a fast, nominal, or slow falling waveform crosses the same V_{T} threshold is denoted as either t_{F1}, t_{F2}, or t_{F3}, respectively. The width of a nominal pulse 10 is

t_{W22}=t_{F2}−t_{R2}.

However, when the rise time is fast (i.e., Rise time=t_{R1}) but the fall time is slow (i.e., Fall time=t_{F3}), the width of the pulse 10 becomes equal to t_{W13}, where

t_{W13}=t_{F3}−t_{R1}.

Likewise, when the rise time is slow (i.e., rise time=t_{R3}) but the fall time is fast (i.e., Fall time=t_{F1}), the width of the pulse 10 becomes equal to t_{W31}, where

t_{W31}=t_{F1}−t_{R3}.

The error introduced by either distortion is the difference between t_{W13} (or t_{W31}) and t_{W22}. By inspection this is

t_{ERROR}=t_{W13}−t_{W22}=(t_{F3}−t_{F2})−(t_{R1}−t_{R2})

or,

t_{ERROR}=t_{W31}−t_{W22}=(t_{F1}−t_{F2})−(t_{R3}−t_{R2}).

Generally speaking, Δ_{F} may represent a change in the fall time (with respect to t_{f2}) and Δ_{R} may represent a change in rise time (with respect to tᵣ₂). Thus, t_{ERROR} is defined as

t_{ERROR}=Δ_{F}−Δ_{R}.

Thus, if Δ_{F} is positive and Δ_{R} is negative, the resultant t_{ERROR} is positive. And, if Δ_{F} is negative and Δ_{R} is positive, the resultant t_{ERROR} is negative. Note that if Δ_{F}=Δ_{R}, the resultant error is zero.

Another source of distortion is due to unequal data dependent delays. FIG. 2 shows a nominal pulse 12 and distortions that are attributable to a delay that occurs from the 1-to-0 transition or from the 0-to-1 transition. The delay of the 0-to-1 logic transition is defined by Δ_{R} and the delay of the 1-to-0 logic transition is defined by Δ_{F}. (see the equations defined above).

Typically, the positions of the pulse 12's edges are reliably and accurately measured with respect to a system clock that drives a flip-flop circuit which produces the pulse 12. In CMOS systems, it is usually the flip-flop element itself that is the root cause of a data dependent distortion. The delay from the clock input of a CMOS flip-flop to its Q output (or, alternately, its Q “bar” output) can assume one of two values depending on whether the output goes from a 0-to-1 or a 1-to-0.

This type of data dependent distortion as well as rise and fall mismatch can be significant in CMOS systems. This is especially true in high frequency sigma-delta DACs. Consider a numerical example where t_{ERROR} due to either rise and fall time mismatch or data dependent flip-flop delay, is 400 ps and the period of the system clock is 100 ns (10 MHz). In sigma-delta DACs operating at mid-scale, the required 50% density of ones usually leads to a repeating “01” pattern; i.e., a square wave. This results in a 400 ps error in a 200 ns time period or a 0.2% voltage error after the sigma-delta waveform is low-pass filtered. This is a significant error because it limits the accuracy of the DAC to approximately nine bits. If one needs a sigma-delta DAC with 16-bit accuracy, one must either reduce the clock frequency (and the system bandwidth) by a factor of 128 and/or employ a complex data encoding scheme. Clearly, any reductions that are made to t_{ERROR} have a significant impact on system performance and cost. In this not unrealistic example, reducing t_{ERROR} by two orders of magnitude to 4 ps allows nearly 16-bit accuracy without any reduction in bandwidth or complex data encoding schemes.

To first type of duty cycle distortion (i.e., due to rise and fall time mismatches) may be reduced or mitigated by careful design the output buffers for matching rise and fall times, setting the threshold voltage of the receivers to compensate for any mismatches in rise and fall time, or by using differential driver and receiver circuits. However, these approaches are not effective at reducing or mitigating data dependent delay distortion.

### SUMMARY

A method and a circuit for correcting duty cycle distortion are presented.

In one example, a delay insertion gate includes first and second field effect transistors that have gates that are respectively coupled to receive first and second signals from an upstream circuit, such as an upstream data latch. The first and second signals are offset by a phase difference and are complements of each other. The delay insertion gate further includes a current mirror, which is coupled to the drain terminals of the first and second transistors. An output node of the delay insertion gate produces a duty cycle corrected signal, which has been corrected for any data dependent switching delays attributed to the upstream circuit.

Alternatively, an example method includes providing a delay insertion gate, receiving first and second signals from an upstream circuit, biasing a gate of the first transistor with the first signal, biasing a gate of the second transistor with the second signal, and outputting a duty cycle corrected timing signal at the drain terminals of the first or second transistors.

In the described examples, the first and second transistors should be matched to at least one transistor within the upstream circuit. Also, the output of the delay insertion gate is to a capacitance. In one example, the capacitance may comprise a parasitic capacitance associated with devices that are downstream from the delay insertion gate.

In an additional example, a delay insertion gate may further comprise a current source that is coupled to source terminals associated with the first and second transistors. The current source may be tailored to mitigate a switching delay associated with the current mirror. These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Certain example embodiments are described below in conjunction with the appended drawing figures, wherein like reference numerals refer to like elements in the various figures, and wherein:

FIG. 1 is a diagram that shows how differences in rise and fall times can cause errors in the duty cycle of a digital waveform;

FIG. 2 is a diagram that shows a nominal pulse and distortions that are attributable to a delay that occurs from a 1-to-0 transition and from a 0-to-1 transition;

FIG. 3 is a logic diagram of a logic circuit and a delay insertion gate, according to an example;

FIGS. 4A-B are timing diagrams showing signals produced by the logic circuit of FIG. 3;

FIGS. 4C-D are timing diagrams that show an output signal produced by the delay insertion gate of FIG. 3, according to an example;

FIG. 5 is a schematic representation of a delay insertion gate, according to an example

FIGS. 6A-B are timing diagrams that show signals produced by the delay insertion gate of FIG. 5, according to an example;

FIG. 7 is a schematic representation of an example current mirror that may be used within a delay insertion gate; and

FIG. 8 is a schematic representation of a delay insertion gate that includes a current source, according to an example.

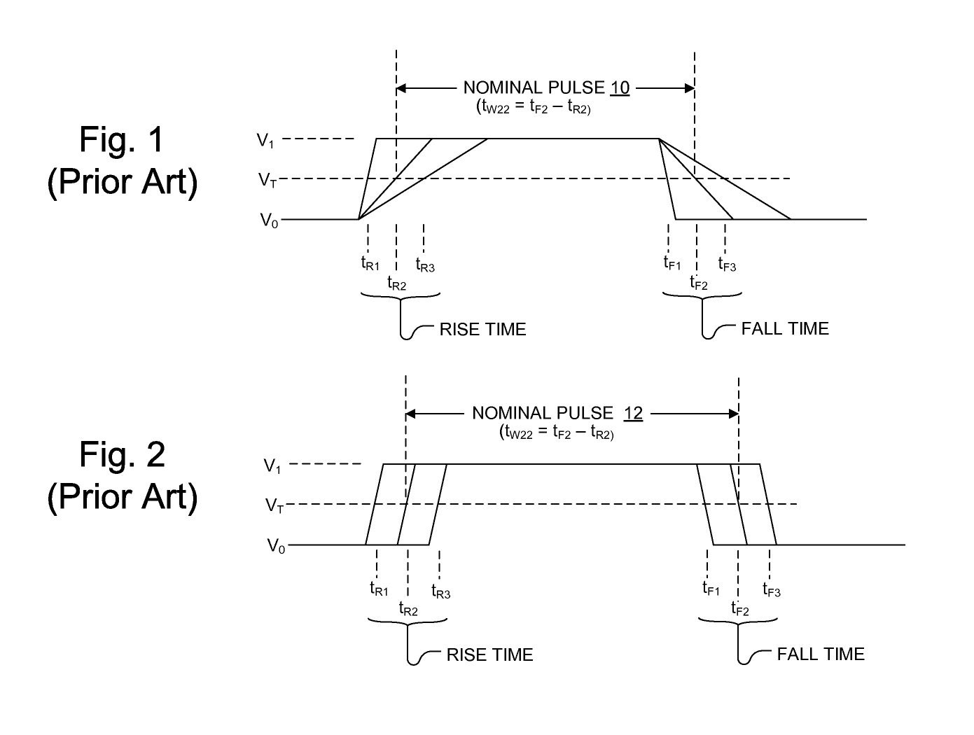

### DETAILED DESCRIPTION

The described delay insertion gate corrects data dependent delay distortion that is generated by CMOS flip-flop circuits. The delay insertion gate receives two complementary signals from an upstream circuit (e.g., latch or flip-flop) and uses these signals to produce a duty cycle corrected signal. The delay insertion gate corrects any data dependent distortion associated with the two signals received from the upstream circuit.

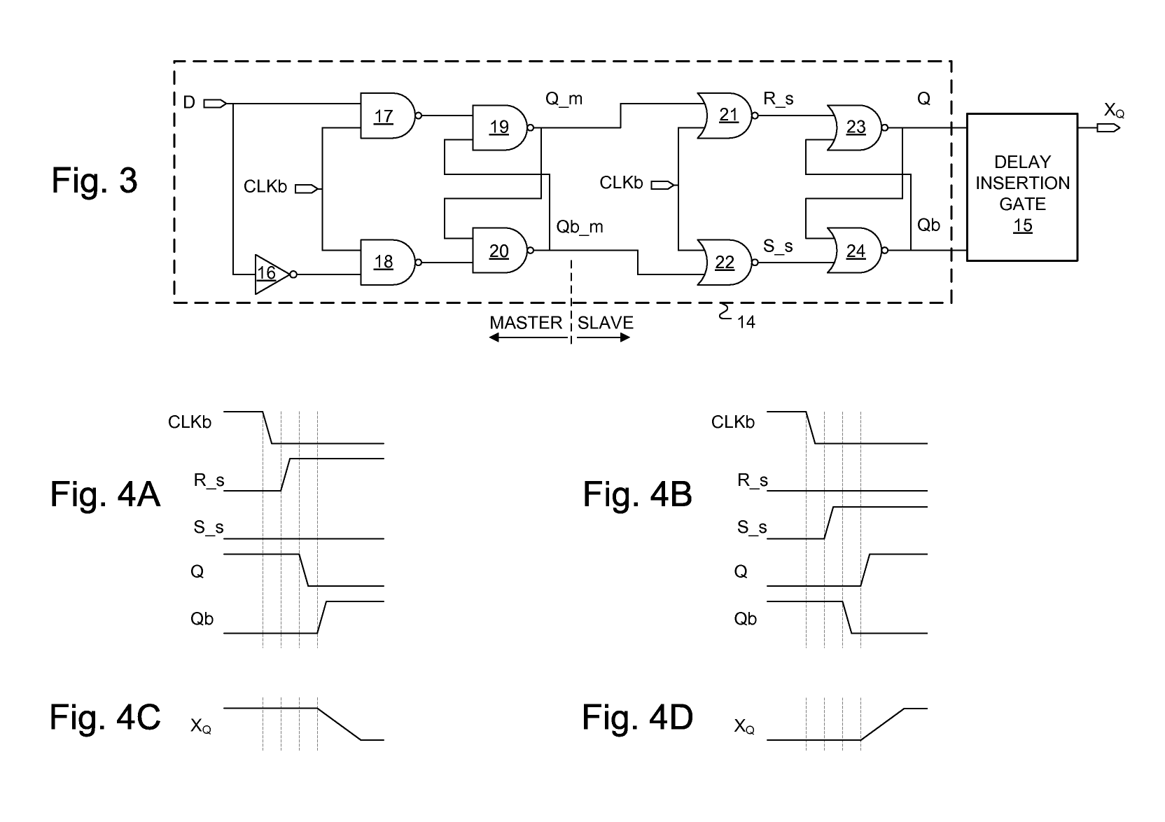

Turning now to the figures, FIG. 3 is a schematic diagram of a static D-type master-slave flip-flop 14 and a delay insertion gate 15. The flip-flop 14 receives an input waveform at its “D” input and produces outputs “Q” and “Qb.” The flip-flop 14 comprises a master latch that includes inverter 16 and NAND logic gates 17-20. The flip-flop 14 also comprises a slave latch that includes NOR logic gates 21-24. Both the master and slave latches are cycled by a clock signal “CLKb,” which, for example, may be provided by inverting a master clock signal “CLK” (not shown).

Although the flip-flop 14 is a basic design without any additional set, reset, or other inputs; nor outputs beyond the complementary Q and Qb, it generally conveys how a flip-flop is coupled to a delay insertion gate. Thus, it should be understood that a variety of other types of flip-flops or other timing circuits may incorporate the described delay insertion gate. Furthermore, for purposes of illustration, the timing diagrams in this disclosure represent the rise and fall times of all the logic gates being equal for all possible input transitions.

FIGS. 4A-B are timing diagrams that show the data dependent delay phenomenon at the output of the NOR gates 23-24, which are connected as a standard RS latch. Initially, when CLKb is high, the R and S inputs to the output RS latch are low. This is ensured by the NOR gates 21-22 which drive the R and S inputs labeled “R_s” and “S_s” in FIG. 3 and FIGS. 4A-B. Before the 1-to-0 transition of CLKb, the “Q_m” and “Qb_m” outputs of the master latch are stable. One gate delay after the CLKb signal goes low either R_s or S_s goes high depending on the state of the Q_m and Qb_m signals from the master latch. Then, two gate delays after the CLKb signal goes low, either the Q output will go low (if it was high before and R_s just went high) or the Qb output will go low (if it was high before and S_s just went high). Finally, three gate delays after the CLKb signal goes low, either the Qb output will go high (if it was low before and R_s went high) or the Q output will go high (if it was low before and S_s went high). The data dependent delay phenomenon can also be observed in Table 1 below.

TABLE 1

| CLKb | R_s | S_s | Q |
|---|---|---|---|
| 1 | 0 | 0 | 1 |
| 0 | 0 | 0 | 1 |
| 0 | 1 | 0 | 1 |
| 0 | 1 | 0 | 0 |
| 0 | 1 | 0 | 0 |
| 1 | 0 | 0 | 0 |
| 0 | 0 | 0 | 0 |
| 0 | 0 | 1 | 0 |
| 0 | 0 | 1 | 0 |
| 0 | 0 | 1 | 1 |

Note that when the Q output changes from a 1 to a 0, this occurs two gate delays after CLKb goes low; but, when the Q output changes from a 0 to a 1, this occurs three gate delays after CLKb goes low. Likewise, when the Qb output changes from a 0 to a 1, this occurs two gate delays after CLKb goes low; but, when the Qb output changes from a 1 to a 0, this occurs three gate delays after CLKb goes low.

To mitigate the data dependent delay phenomenon, the delay insertion gate 15 inserts an extra gate delay on the 1-to-0 transition of the Q output but does not do so on the 0-to-1 transition of the Q output. The delay insertion gate 15 follows the flip-flop outputs Q and Qb and provides a signal output “X_{Q}” that compensates for the flip-flop delay so that the overall delay from the clock edge to the output is essentially independent of the data itself. FIGS. 4C-D are timing diagrams that show the output X_{Q} which has been corrected so that it has equal delays during both the 1-to-0 and the 0-to-1 transitions.

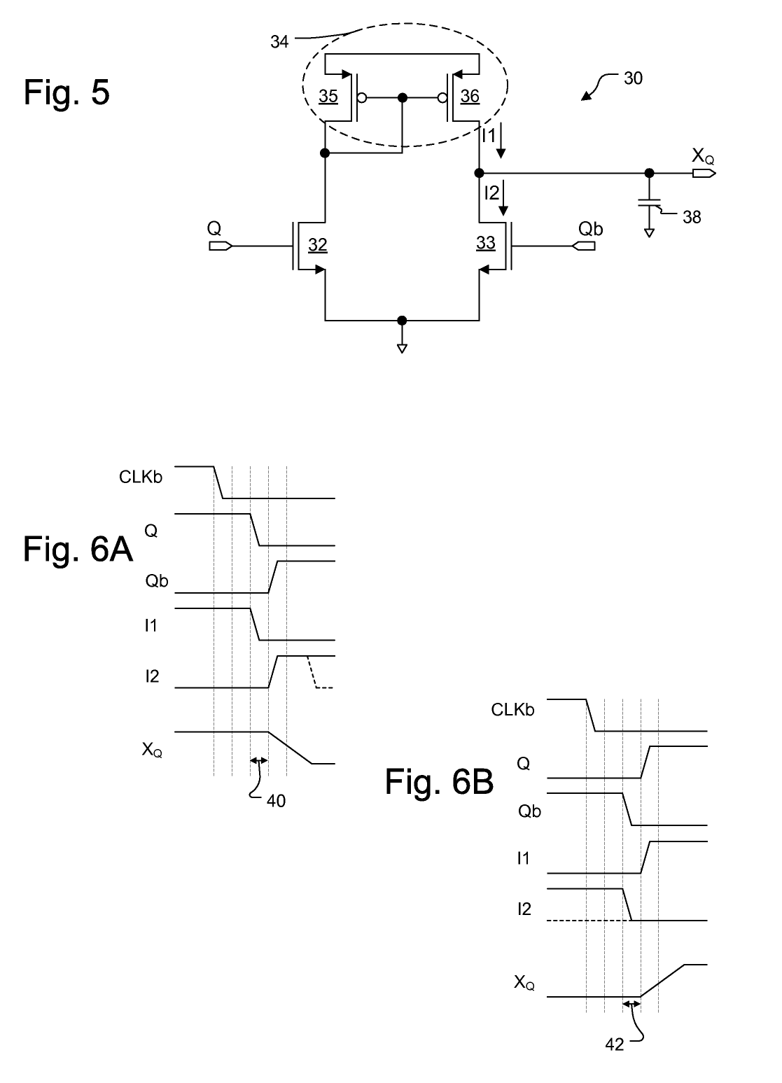

FIG. 5 shows a schematic diagram of a delay insertion gate 30. The delay insertion gate 30 comprises field effect transistors 32-33 and a current mirror circuit 34. The current mirror circuit 34, which comprises field effect transistors 35-36, is coupled to the drain terminals of each of the transistors 32-33.

Preferably, the transistors 32-33 should match closely to the implementation of the transistors used in the upstream circuit (i.e., channel width, channel length, threshold voltage, etc.). For example, to correct the duty cycle distortion of the flip-flop 14, the transistors 32-33 should be of the same implementation as the transistors used in the NOR gates 23-24 (see FIG. 3). Thus, the transistors are NMOS transistors. Alternatively, if a NAND gate was upstream to the transistors 32-33, the transistors 32-33 would need to be PMOS. In that case, the current mirror circuit 34 would comprise NMOS transistors. This implementation may increase the switching speed of the current mirror circuit 34.

FIGS. 6A-B are timing diagrams that show the operation of the delay insertion gate 30. The delay insertion gate 30 receives two input signals, Q and Qb, respectively at the gates of the transistors 32-33. The signals Q and Qb are complements of each other. It should also be noted that these signals have data dependent distortion, which occurs during the low-to-high and high-to-low transitions. For example, in a 1-to-0 transition on the Q output, Qb goes high three gate delays after the CLKb signal goes low. However, for a 0-to-1 transition on the Q output, Qb goes low two gate delays after the CLKb signal goes low.

In FIG. 6A, when Q is high, a current I1 flows through the transistor 32. The transistor 33 is off, and the current I1 is reflected to the X_{Q} output by the current mirror 34 so that the output X_{Q} remains high. Later, when Q goes low, this pull-up current ceases (I1=0) but the X_{Q} output stays high momentarily due to a capacitance 38 at the X_{Q} output. This momentary holding of the data state creates a delay 40 that compensates for the data dependent delay distortions in the Q and Qb signals. In general, the X_{Q} output will remain floating for a full gate delay before being driven either high or low.

One gate delay after Q goes low, Qb goes high. The transistor 33 turns on and the transistor 32 turns off. A current I2 then flows through the transistor 33. The current I2 pulls the X_{Q} output node low. When the capacitor 38 is discharged, the current I2 goes to zero. The transistor 33 continues to hold X_{Q} low until Qb goes low.

FIG. 6B shows what happens when Qb transitions from high to low. At the beginning of this transition, transistor 36 is off. When transistor 33 is turned off, the X_{Q} output is momentarily held low by the capacitance on this node. This momentary holding of the data state creates a delay 41, which again compensates for the data dependent delay distortion in the Q and Qb signals. One gate delay later, Q goes high.

In many implementations, a capacitor does not need to be explicitly added to the delay insertion gate 30. Generally speaking, the parasitic capacitance of downstream circuitry following the delay insertion gate is large enough so that it is not necessary to explicitly add a capacitor to the circuit. It should also be noted that FIGS. 6A-B show the maximum possible current for I2 (if X_{Q} were shorted to a voltage source). The actual I2 current that flows is shown with a dotted line. Note that the currents I1 and I2 do not overlap.

An important element of an insertion gate is the current mirror. Ideally, the current mirror should have a response time that is much faster than the delay time associated with the upstream circuit (i.e., the driving flip-flop). However, in practice, this requirement is difficult to meet and the two-transistor current mirror structure shown in FIG. 5 has a slow turn-off, which would contribute additional delay distortion.

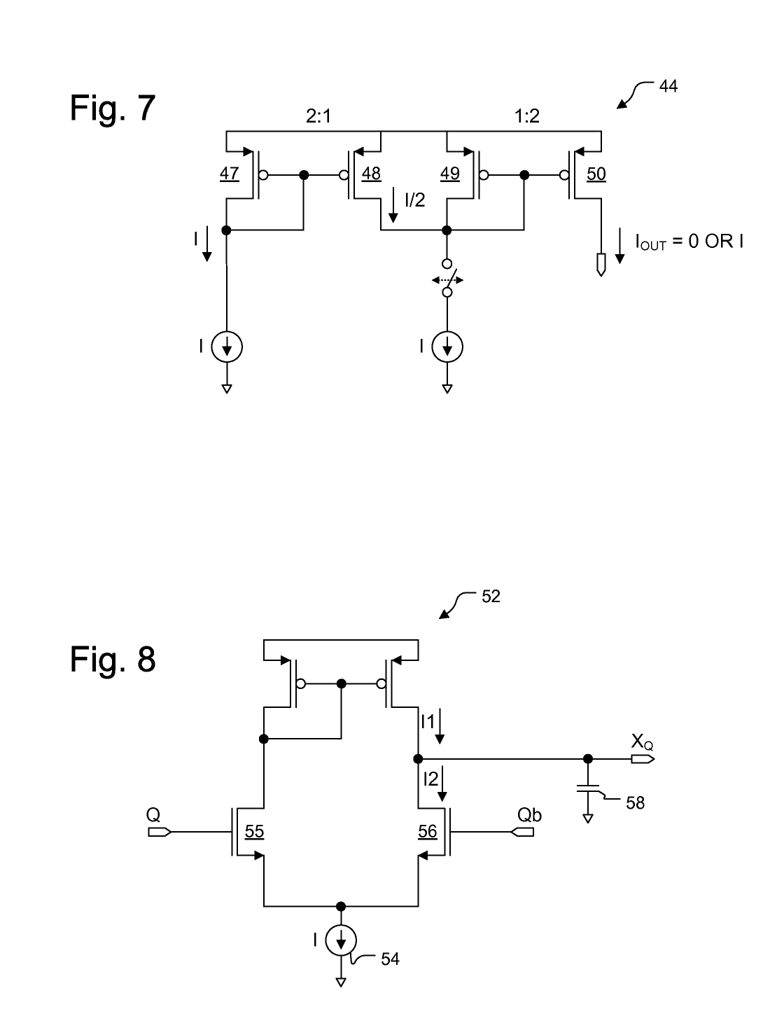

FIG. 7 shows a current mirror 44 that may be used to improve the response time of the two-transistor current mirror. Here, the current mirror 44 comprises two stages. One stage includes field effect transistors 47-48. The other stage includes field effect transistors 49-50, which have a current gain of two. The current into this stage has a value of either plus or minus ½. Thus, similar to the current mirror 34, the net result is that the output current is either I or zero, however the gate voltage on transistors 49-50 is actively discharged.

An alternative approach to improving the response time of the two-transistor current mirror is to slow the response of the input transistors (i.e., transistors 32-33 in FIG. 5) by limiting the current supplied to their source terminals. When doing this, it is important to match the two current sources (i.e., one match to transistor 32 and one match to transistor 33).

FIG. 8 shows a delay insertion gate 52 comprising a current source 54. The current source 54 is coupled to the source terminals of field effect transistors 55-56. The current source 54 essentially acts as a regulator and limits the rate of change of the voltage (dV/dt) across an output capacitance 58 (i.e., the rise and fall times). Because there is always a period of time before each transition when both the transistors 55-56 are off, it is possible for both transistors to share the common current source 54; thus ensuring a perfect match. Furthermore, the amount of current through the current supply may be tailored to mitigate a switching delay associated with the current mirror.

Those skilled in the art will understand that changes and modifications may be made to these examples without departing from the true scope and spirit of the present invention, which is defined by the claims. Thus, the presented figures are intended to generally convey example arrangements of a delay insertion gate. Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

I claim:

1. A method for correcting duty cycle distortion, the method comprising:
providing a delay insertion gate that comprises first and second field effect transistors and a current mirror, wherein the drain terminals of the first and second transistors are coupled to the current mirror;
receiving first and second signals from an upstream circuit, wherein the first and second signals are offset from each other by a phase difference;
biasing a gate of the first transistor with the first signal;
biasing a gate of the second transistor with the second signal; and
outputting a duty cycle corrected timing signal at the drain terminal of at least one of the first and second transistors.

2. The method of claim 1, wherein the first and second transistors are matched to at least one transistor within the upstream circuit.

3. The method of claim 1, wherein the delay insertion gate further comprises a current source, wherein the current source is coupled to source terminals associated with the first and second transistors.

4. The method of claim 3, wherein the current source is tailored to mitigate a switching delay associated with the current mirror.

5. The method of claim 1, wherein the drain terminal of the second transistor is coupled to a capacitance.

6. The method of claim 5, wherein the capacitance comprises a parasitic capacitance associated with devices that are downstream from the delay insertion gate.

7. The method of claim 1, wherein the first and second signals are output from a data latch.

8. The method of claim 1, wherein the first and second signals each have a data dependent switching delay.

9. The method of claim 8, wherein the data dependent switching delay is attributed to a gate propagation delay within a data latch.

10. A delay insertion gate for correction duty cycle distortion, comprising:
first and second field effect transistors, wherein the gates of the first and second transistors are respectively coupled to receive first and second signals from an upstream circuit, wherein the first and second signals are offset from each other by a phase difference, and wherein the first and second signals each have an data dependent switching delay that is attributed to a gate propagation delay within the upstream circuit;
a current mirror, wherein the drain terminals of the first and second transistors are coupled to the current mirror; and
an output node coupled to at least one of the drain terminals of the first and second transistors, wherein the output node is configured to produce a duty cycle corrected timing signal.

11. The duty cycle correction of claim 10, wherein the upstream circuit comprises a data latch.

12. The delay insertion gate of claim 10, wherein the first and second transistors are matched to at least one transistor within the upstream circuit.

13. The delay insertion gate of claim 10, wherein the delay insertion gate further comprises a current source, wherein the current source is coupled to source terminals associated with the first and second transistors.

14. The delay insertion gate of claim 13, wherein the current source is tailored to mitigate a switching delay associated with the current mirror.

15. The delay insertion gate of claim 10, further comprising a capacitance coupled to at least one of the drain terminals of the first and second transistors.

16. The method of claim 15, wherein the capacitance comprises a parasitic capacitance associated with devices that are downstream from the delay insertion gate.
